(19) United States
(12) Patent Application Publication
(10) Pub. No.: US 2023/0411714 A1
(43) Pub. Date: Dec. 21, 2023

(54) SENSING PCB STRUCTURE OF BATTERY UNIT

(71) Applicant: Elentec., LTD, Hwaseong-si (KR)

(72) Inventor: Seung Tae JUNG, Hwasung-si (KR)

(73) Assignee: Elentec., LTD, Hwaseong-si (KR)

(21) Appl. No.: 18/070,515

(22) Filed: Nov. 29, 2022

(30) Foreign Application Priority Data
Jun. 20, 2022 (KR) 10-2022-0075051

(51) Int. Cl. H01M 10/48; H01M 50/213; H01M 50/509; H01M 50/519; H01M 50/569; H05K 1/02; G01R 31/36

(52) U.S. Cl. CPC H01M 10/482; H01M 50/213; H01M 50/509; H01M 50/519; H01M 50/569; H05K 1/0296; G01R 31/3644; H05K 2201/09027; H05K 2201/10037; H05K 2201/10272

(57) ABSTRACT

Proposed is a sensing PCB of a battery unit, the sensing PCB being coupled to the battery unit in which a plurality of cylindrical battery cells, each of which has an upper surface provided with a positive electrode and an negative electrode, are mounted, and being electrically connected to an electrode network for connecting the plurality of battery cells, and the sensing PCB including a “C”-shaped substrate part coupled to the battery unit, a plurality of electrode parts arranged on the substrate part and making contact with ends of the electrode network, a pattern part formed on the substrate part and selectively connected to the plurality of electrode parts, and an output part located on the substrate part, electrically connected to the pattern part, having a connection terminal, and outputting an electric signal for each connection section of the electrode network through the pattern part.

### CROSS REFERENCE TO RELATED APPLICATION

The present application claims priority to Korean Patent Application No. 10-2022-0075051, filed Jun. 20, 2022, the entire contents of which is incorporated herein for all purposes by this reference.

### BACKGROUND OF THE INVENTION

### Field of the Invention

The present disclosure relates to a sensing PCB structure of a battery unit.

### Description of the Related Art

With the spread of smart devices, the use of rechargeable and reusable secondary batteries is also increasing.

Recently, such secondary batteries have been increasingly applied to electric vehicles (EVs) such as electric cars and electric trains, and an energy storage system (ESS) for industrial and home use.

An ESS is a system technology that increases energy efficiency through charging (storage) and discharging (use) of energy storage devices. The energy storage devices are generally composed of a battery unit in a form in which a plurality of unit lithium-ion battery cells are mounted in a housing and then electrically connected. An example of such a battery unit structure technology is disclosed in Korean Patent No. 10-1724770 (application date: Jun. 4, 2010, publication date: Apr. 3, 2017, hereinafter referred to as the “related art”).

In the case of a battery unit, because a plurality of battery cells are densely packed, it is required to adopt a structure for effectively lowering heat generated during charging/discharging of battery cells to thereby prevent deterioration of charging/discharging efficiency of the battery cells caused by temperature change. Also, there is a need to continuously monitor a charging/discharging state of the battery cells in order to prevent occurrence of power abnormalities and operation abnormalities of the battery unit.

However, the related art may be suitable for a low-capacity battery unit structure, but is difficult to apply in an ESS system that requires a larger number of battery cells to be mounted therein. Furthermore, the related art lacks of a heat dissipation structure for effectively lowering heat generated from such a large number of battery cells, and has no configuration for continuously monitoring the charge/discharge state of the battery cells. This makes it difficult to prevent occurrence of secondary accidents caused by an increase in temperature inside the battery unit and occurrence of power abnormalities and operation abnormalities.

The foregoing is intended merely to aid in the understanding of the background of the present disclosure, and is not intended to mean that the present disclosure falls within the purview of the related art that is already known to those skilled in the art.

### SUMMARY OF THE INVENTION

Accordingly, the present disclosure has been made keeping in mind the above problems occurring in the related art, and the present disclosure provides a sensing PCB of a battery unit, the sensing PCB being capable of monitoring a power state of the battery unit without impairing heat dissipation inside the battery unit.

In order to achieve the above objective, according to one aspect of the present disclosure, there is provided a sensing PCB of a battery unit, the sensing PCB being coupled to the battery unit in which a plurality of cylindrical battery cells, each of which has an upper surface provided with a positive electrode and an negative electrode, are mounted, and being configured to be electrically connected to an electrode network configured to connect the plurality of battery cells in series and parallel and provided in the form of a plurality of separated busbars, and the sensing PCB including: a substrate part provided in a “C” shape and fixedly coupled to the battery unit by a coupling means in a direction of the electrode network of the battery unit; a plurality of electrode parts provided as a plurality of conductors arranged on a lower surface of the substrate part facing the direction of the electrode network, and configured to make contact with respective ends of the electrode network when the substrate part is fixedly coupled to the battery unit; a pattern part formed on the substrate part and provided in the form of a printed pattern selectively connected to the plurality of electrode parts; and an output part located on an upper surface of the substrate part, configured to be electrically connected to the pattern part, having a connection terminal to which an input terminal of a measuring device for measuring an electrical signal is connected, and configured to output an electric signal for each connection section of the electrode network to which the plurality of battery cells are connected through the pattern part.

Here, each of the electrode parts may be provided as a conductor having elastic force.

In detail, each of the electrode parts may be provided in the form of a plate spring convex downward.

Furthermore, each of the electrode parts may be brought into close contact with each end of the electrode network by the elastic force when the substrate part is fixed to the battery unit in the direction of the electrode network by the coupling means.

Meanwhile, the battery unit may be provided in a structure in which a first cell group in which a plurality of battery cells form rows and columns, a second cell group in which a plurality of battery cells form rows and columns and spaced apart from the first cell group, and a third cell group in which a plurality of battery cells form rows and columns and disposed between the first and second cell groups are fixedly arranged in a housing so that the positive electrode of each of the battery cells of each of the cell groups faces upward, and the electrode network is disposed on an upper surface of the housing.

Here, the electrode network may include: at least one pair of first busbars located on the upper surface of the housing between a row of battery cells and another adjacent row of battery cells that are adjacent in a column direction among the plurality of battery cells of the first and second cell groups, and configured to be connected to the respective positive electrodes of the row of battery cells and the respective negative electrodes of the another adjacent row of battery cells to connect the pluralities of battery cells of the first and second cell groups in parallel in a row direction and in series in the column direction; a second bus bar configured to connect unconnected electrodes of an outermost row of battery cells in which any one of the positive electrodes and the negative electrodes are connected to the first busbar among the plurality of battery cells of the first and second cell groups, and electrodes of opposite polarities to the unconnected electrodes among the electrodes of a column of battery cells of the third cell group; and a pair of third busbars configured to be connected to unconnected electrodes of an outermost row of battery cells in which any one of the positive electrodes and the negative electrodes are connected to the first busbar while not being connected to the second busbar among the plurality of battery cells of the first and second cell groups, and each of which has a connection terminal for transmitting power output from the plurality of battery cells connected to the first and second busbars to outside.

In addition, the output part may output an electrical signal for each connection section of the plurality of battery cells through the pattern part, the electrical signal being input from each of the electrode parts electrically connected to the first, second, and third busbars in contact therewith.

According to the sensing PCB of the battery unit according to the present disclosure, since the substrate part has a “C” shape with one open side rather than a simple plate shape, when a misalignment occurs between the coupling recess of the upper housing and the coupling hole of the substrate part due to a contact area and tolerance between the electrode part and the busbar, it is possible to easily overcome the misalignment. Also, it is possible to enable the substrate part to be coupled on the upper surface of the upper housing without closing an open heat dissipation region formed in the upper surface of the upper housing.

In addition, according to the sensing PCB of the battery unit according to the present disclosure, since the electrode part is provided in the form of a plate spring convex toward the coupling direction of the substrate part, when the substrate part is fixedly coupled to the upper surface of the upper housing by the coupling means, it is possible to enable the electrode part to maintain a close contact state with the electrode network. Also, it is possible to prevent rotational loosening of the coupling means by elastic restoring force to push the substrate part in the direction opposite to the coupling direction. This eliminates the need for the sensing PCB to be joined to the electrode network by soldering or the like, thereby making it easy to partially replace the sensing PCB when a defect or failure occurs, and simplifying the entire manufacturing process of the battery unit.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 a view schematically illustrating a battery unit to which a sensing PCB according to an exemplary embodiment of the present disclosure is applied;

FIG. 2 is a view partially illustrating a connection form between the sensing PCB according to the exemplary embodiment of the present disclosure and an electrode network; and

FIG. 3 shows side sectional views (A), (B) and (C) illustrating an electrical connection between an electrode part and a busbar in the process of coupling the sensing PCB on an upper housing by a coupling means in a region A illustrated in FIG. 2.

### DETAILED DESCRIPTION OF THE INVENTION

Hereinafter, an exemplary embodiment of a sensing PCB of a battery unit according to the present disclosure will be described in detail with reference to the accompanying drawings.

Throughout the drawings, like reference numerals refer to like parts. Specific structural and functional descriptions of embodiments of the present disclosure disclosed herein are only for illustrative purposes of the embodiments of the present disclosure. Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

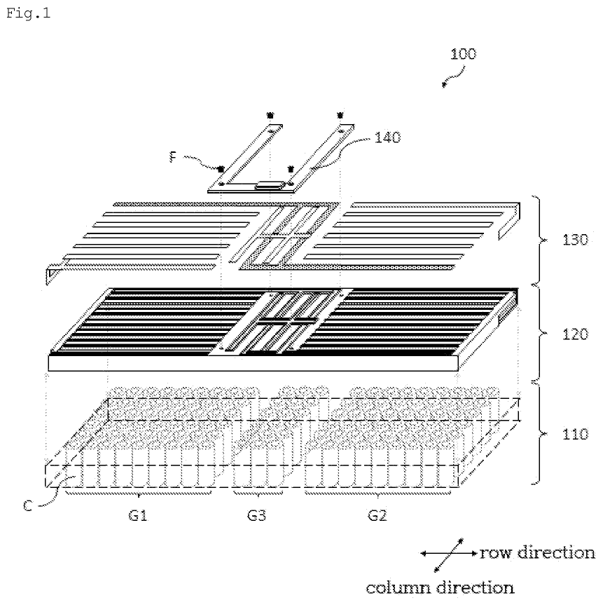

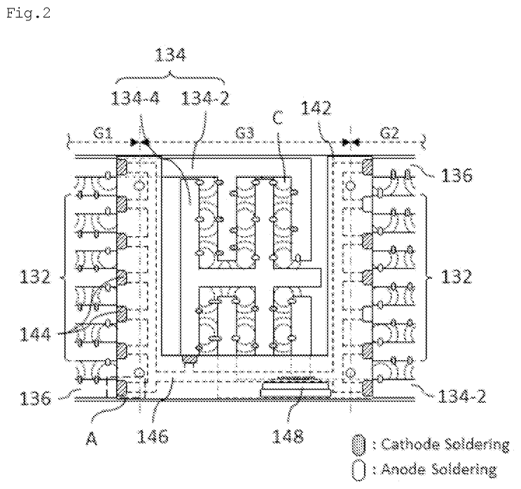

FIG. 1 a view schematically illustrating a battery unit 100 to which a sensing PCB 140 according to an exemplary embodiment of the present disclosure is applied. FIG. 2 is a view partially illustrating a connection form between the sensing PCB 140 according to the exemplary embodiment of the present disclosure and an electrode network 130.

Referring to FIGS. 1 to 2, the battery unit 100 according to the exemplary embodiment of the present disclosure may include a lower housing 110, an upper housing 120, the electrode network 130, and the sensing PCB 140.

The lower housing 110 may be provided in a quadrangular basket shape having an open upper surface and having an inner space in which a plurality of cylindrical battery cells C, each of which has an upper surface provided with a positive electrode and a negative electrode, are fixedly arranged to form rows and columns in a predetermined group. A plurality of support recesses (not illustrated) for supporting lower portions of the plurality of battery cells C may be formed in a bottom surface of the inner space in which the plurality of battery cells C are fixedly arranged. Here, the support recesses may be provided in a shape in which a circular recess conforming to the shape of a lower surface of each of the battery cells C or a square partition structure having a width and a width corresponding to the diameter of the lower surface is repeatedly formed in the row and column directions. The support recesses may be formed at a predetermined interval so that the battery cells C are spaced apart from each other at a predetermined interval.

The plurality of battery cells C fixedly arranged in the lower housing 110 may form a plurality of cell groups G1, G2, and G3 in each of which a predetermined number of battery cells C form rows and columns. The plurality of battery cells C may be fixed in such a manner that the cell groups G1, G2, and G3 are spaced apart from each other at a predetermined interval along the longitudinal direction of the lower housing 110. At this time, the cell groups G1, G2, and G3 formed by the plurality of battery cells C may be composed of a first cell group G1, a second cell group G2, and a third cell group G3 arranged along the longitudinal direction of the lower housing 110. The first cell group G1 may include a plurality of battery cells C arranged to form rows and columns, and may be disposed in a first region of the inner space of the lower housing 110. The second cell group G2 may include a plurality of battery cells C of the same number as those of the first cell group G1 arranged to form rows and columns, and may be disposed between the first cell group G1 and the second cell group G2. The third cell group G3 may include a plurality of battery cells C of a smaller number than those of the first cell group G1 or the second cell group G2 arranged to form rows and columns, and may be disposed in a second region of the inner space of the lower housing 110 opposite to the first region in which the first cell group G1 is disposed. The arrangement of the first, second, and third cell groups G1, G2, and G3 may be achieved in such a manner that the battery cells C forming a single row or column are connected to each other in parallel, with the positive electrodes thereof being joined to the electrode network 130 in the form of a plurality of separate busbars of various shapes, and the parallel-connected battery cells C in each row or column are connected in series with the parallel-connected battery cells C in another adjacent row or column. The arrangement of the first, second, and third cell groups G1, G2, and G3 may be determined differently depending on the voltage and current flowing through opposite ends of the electrode network 130 connecting the plurality of battery cells C. The electrical connection of the first, second, and third cell groups G1, G2, and G3 will be described in more detail in the description of the configuration of the electrode network 130 which will be described later.

The upper housing 120 may be coupled to the lower housing 110 to cover the open upper surface of the lower housing 110. At this time, the upper housing 120 may be coupled to the open upper surface of the lower housing 110, thereby forming a rectangular parallelepiped shape conforming to the shape of the battery unit 100 according to the exemplary embodiment of the present disclosure. The upper housing 120 may be provided in a shape in which a region of an upper portion thereof corresponding to the upper surface of each of the battery cells C on which the positive electrode is disposed is removed. Each removal region may be connected to another adjacent removal region to form a straight line. As illustrated in FIGS. 1 to 2, the upper housing 120 may be provided in a shape in which a region corresponding to an imaginary straight line that connects the upper surfaces of a row of battery cells C forming each of the first cell group G1 and the second cell group G2 is removed, and a region corresponding to an imaginary straight line that connects the upper surfaces of a column of battery cells C forming the third cell group G3 is removed. The removal regions of the upper housing 120 may be provided to allow, when the electrode network 130 which will be described later is disposed on the upper surface of the upper housing 120, the positive electrodes of the plurality of battery cells C arranged in an inner space formed by the lower housing 110 and the upper housing 120 to be joined and connected to a plurality of busbars forming the electrode network 130. The removal regions of the upper housing 120 may be used to dissipate heat generated from the plurality of battery cells C arranged in the inner space formed by the lower housing 110 and the upper housing 120 to the outside. Meanwhile, a plurality of coupling recesses (not illustrated) to which the sensing PCB 140 which will be described later is fixedly coupled by a coupling means F may be provided in the center of the upper surface of the upper housing 120 corresponding to the region in which in the third cell group G3 is disposed. The plurality of coupling recesses may be formed in a region excluding the regions in which the plurality of busbars forming the electrode network 130 are arranged.

The electrode network 130 may be disposed in a region of the upper surface of the upper housing 120 except for the removal regions. As illustrated in FIG. 2, the electrode network 130 may include a first busbar 132, a second busbar 134, and a third busbar 136. Here, the first busbar 132 may be provided as a pair of first busbars 132. The first busbars 132 may be arranged between a plurality of straight removal regions formed in the region corresponding to each of the first cell group G1 and the second cell group G2 of the upper housing 120. The second busbar 134 may include a pair of separate busbars 134-2 and a connection busbar 134-4. Here, among the pair of separate busbars 134-2, one separate busbar 134-2 may be disposed in any one of the outermost regions of the plurality of straight removal regions formed in the region corresponding to the first cell group G1, and any one or more of a plurality of separated removal regions extending from the any one of the outermost regions and formed in the region corresponding to the third cell group G3; and the remaining separate busbar 134-2 may be disposed at a position diagonal and symmetrical with the position of the one separation busbar 134-2, that is, in any one of the outermost regions of the plurality of straight removal regions formed in the region corresponding to the second cell group G2, and any one or more of the plurality of separated removal regions extending from the any one of the outermost regions and formed in the region corresponding to the third cell group G3. The connection busbar 134-4 may be disposed in the region in which no separate busbars 134-2 are arranged among the regions adjacent to the separated removal regions formed in the region corresponding to the third cell group G3. The third busbar 136 may be provided as a pair of third busbars 136. The third busbars 136 may be respectively formed in the outermost region of the plurality of straight removal regions formed in the region corresponding to the first cell group G1 and the outermost region of the plurality of straight removal regions formed in the region corresponding to the second cell group G2, the outermost regions being not connected to the first and second busbars 132 and 134. The third busbars 136 may extend in the lateral direction of the upper housing 110.

Here, each of the first busbars 132 may be connected to the positive electrodes of each row of battery cells C of the first and second cell groups G1 and G2, and may be connected (soldered) to the positive electrodes of a row of battery cells C and the negative electrodes of another adjacent row of battery cells C, so that the plurality of battery cells C forming the first and second cell groups G1 and G2 may be connected in parallel in the row direction in series in the column direction. Here, the electrodes of the battery cells C of the first cell group G1 and those of the battery cells C of the second cell group G2, which are connected to the respective first busbars 132, may be different from each other. In detail, the electrodes of a row of battery cells C of the first cell group G1 and those of a row of battery cells C of the second cell group G2, which are connected to the first busbars 132 on the same line, may be different from each other so that when all of the battery cells C of the first, second, and third cell groups G1, G2, and G3 are electrically connected by the second busbar 134 which will be described later, the first cell group G1 and the second cell group G2 are connected in series. Each of the pair of separate busbars 134-2 of the second busbar 134 may connect, among outermost rows of battery cells C of the first and second cell groups G1 and G2 in which not all the electrodes are connected to the first busbars 132, unconnected electrodes of any one row of battery cells C to any one of the positive electrodes and the negative electrodes of the battery cells C of the third cell group G3. The connection busbar 134-4 may connect the electrodes of the battery cells C of the third cell group G3, which are not connected to the separate busbars 134-2, while connecting the first, second and third cell groups G1, G2, and G3 in series. In addition, each of the pair of third busbars 136 may be connect to, among the battery cells C of the first and second cell groups G1 and G2, unconnected electrodes of an outermost row of battery cells C in which any one of the positive electrodes and the negative electrodes are connected to the first busbar 132 while not being connected to the separate busbar 134-2. An outer end of each of the third busbars 136 may be bent and exposed in the lateral direction of the lower housing 110 and the upper housing 120 coupled to each other, so that DC power may be supplied from the battery cells C of the first, second, and third cell groups G1, G2, and G3 to the outside by using the respective outer ends exposed laterally as positive electrodes.

Referring to FIG. 2, the sensing PCB 140 may partially connected to the first, second, and third busbars 132, 134, and 136, and may be connected to a separate measuring device for measuring an electrical signal for each connection section of the electrode network 130 to which the plurality of battery cells C forming the first, second, and third cell groups G1, G2, and G3 are connected. The sensing PCB 140 may include a substrate part 142, an electrode part 144, a pattern part 146, and an output part 148.

The substrate part 142 may provide a region in which the electrode part 144, the pattern part 146, and the output part 148, which will be described later, are arranged to be coupled or formed on a surface thereof. The substrate part 142 may be provided in a “C” shape, and may be fixed to the center of the upper surface of the upper housing 120 corresponding to the region in which the third cell group G3 is disposed through a separate coupling means F. Here, the substrate part 142 may be made from a non-conductive polymer in a “C” shape with one open side. Thus, when coupling and fixing the substrate 142 on the upper surface of the upper housing 120 through the coupling means F and aligning the position of the electrode part 144 which will be described later to be electrically connected to each of the first, second, and third bus bars 132, 134, and 136, position adjustment may be easier compared to a simple plate-type structure. Also, when coupling the substrate part 142 to the center of the upper surface of the upper housing 120 by passing the coupling means F such as a screw through a coupling hole formed in the substrate part 142 and then screwing the coupling means F in a coupling recess formed in the center of the upper surface of the upper housing 120, even when the coupling recess formed in the center of the upper surface of the upper housing 120 and the coupling hole of the substrate part 142 are slightly misaligned due to tolerance, etc., such a misalignment may be easily overcome through deformation. In addition, such a shape of the substrate part 142 may maintain the removal region of the upper housing 120 formed corresponding to the region in which the third cell group G3 is disposed in an open state, thereby preventing a decrease in air-cooling heat dissipation efficiency for heat generated from the battery cells C forming the third cell group G3 in the inner space formed by the lower housing 110 and the upper housing 120 coupled to each other.

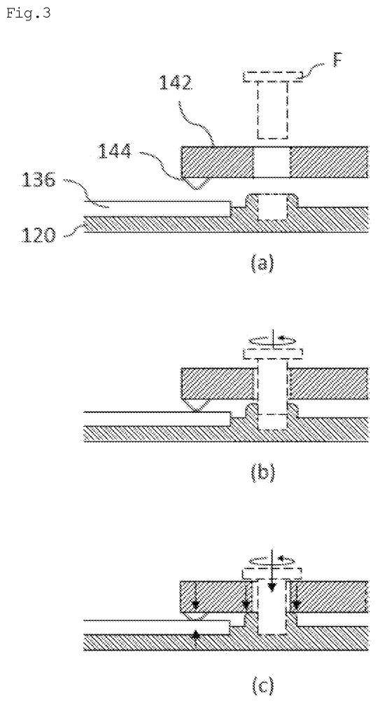

FIGS. 3A, 3B, and 3C are side sectional views illustrating an electrical connection between the electrode part 144 and a busbar in the process of coupling the sensing PCB 140 on the upper housing 120 by the coupling means F in a region A illustrated in FIG. 2.

Referring to FIGS. 3A, 3B, and 3C, a plurality of electrode parts 144 may be provided as a plurality of conductors arranged on a lower surface of the substrate part 142 facing the direction of the electrode network 130. Each of the electrode parts 144 may be partially brought into contact with each of the first, second, and third busbars 132, 134, and 136 when the substrate part 142 is coupled and fixed to the upper surface of the upper housing 120 by the coupling means F. In this case, the electrode part 144 may be provided in the form of a plate spring protruding downward corresponding to the direction of the electrode network 130. When the lower surface of the substrate part 142 is positioned to face the upper surface of the upper housing 120 as illustrated in FIG. 3A and then the substrate part 142 is fixed to the upper surface of the upper housing 120 by screwing the coupling means F as illustrated in FIG. 3B, the electrode part 144 may be deformed under pressure while in contact with each of the first, second, and third busbars 132, 134, and 136 as the gap between the upper surface of the upper housing 120 and the lower surface of the substrate part 142 is gradually reduced by the coupling means F. At this time, as illustrated in FIG. 3C, when the substrate part 142 is in close contact with the upper surface of the upper housing 120 by the coupling means F, the electrode part 144 may expand in the direction opposite to the coupling direction of the substrate part 142 to push the substrate part 142 in the corresponding direction, thereby maintaining strong physical contact with each of the first, second, and third busbars 132, 134, and 136. At the same time, the substrate part 142 may push against a screw head of the coupling means F, which is fixed to the upper housing 120 coupled in a state in which the screw head is caught in the coupling hole, in the direction opposite to the coupling direction, thereby increasing contact force between the substrate part 142 and the screw head and thus preventing rotational loosening caused by a decrease in coupling force of the coupling means F. Such a connection method implemented by physical contact of the electrode part 144 may eliminate the need for the sensing PCB 140 of the battery unit 100 according to the exemplary embodiment of the present disclosure to be joined to the electrode network 130 by soldering or the like. This makes it easy to partially replace the sensing PCB 140 when a defect or failure occurs, and simplifies the entire manufacturing process of the battery unit 100.

The pattern part 146 may be formed on the substrate part 142, and may be provided in the form of a printed pattern selectively connected to the plurality of electrode parts 144. The substrate part 142 and the pattern part 146 may form a printed circuit board (PCB) shape in which a conductive pattern is printed on a non-conductive plate-shaped polymer. The pattern part 146 may be provided to have separated multi-layer patterns formed through non-conductive coating so that each pattern is connected only through a preset connection path without contact between the patterns.

The output part 148 may be located on an upper surface of the substrate part 142, may be electrically connected to the pattern part 146, and may have a connection terminal to which an input terminal (not illustrated) of the measuring device (not illustrated) for measuring an electrical signal is connected. The output part 148 may output an electric signal for each connection section of the electrode network 130 to which the plurality of battery cells C are connected through the pattern part 146. In detail, an electrical signal for each connection section of the plurality of battery cells C that is input from each of the electrode parts 144 electrically connected to the first, second, and third busbars 132, 134, and 136 in contact therewith may be output through the pattern part 146.

According to the sensing PCB of the battery unit according to the present disclosure, since the substrate part has a “C” shape with one open side rather than a simple plate shape, when a misalignment occurs between the coupling recess of the upper housing and the coupling hole of the substrate part due to a contact area and tolerance between the electrode part and the busbar, it is possible to easily overcome the misalignment. Also, it is possible to enable the substrate part to be coupled on the upper surface of the upper housing without closing an open heat dissipation region formed in the upper surface of the upper housing.

In addition, according to the sensing PCB of the battery unit according to the present disclosure, since the electrode part is provided in the form of a plate spring convex toward the coupling direction of the substrate part, when the substrate part is fixedly coupled to the upper surface of the upper housing by the coupling means, it is possible to enable the electrode part to maintain a close contact state with the electrode network. Also, it is possible to prevent rotational loosening of the coupling means by elastic restoring force to push the substrate part in the direction opposite to the coupling direction. This eliminates the need for the sensing PCB to be joined to the electrode network by soldering or the like, thereby making it easy to partially replace the sensing PCB when a defect or failure occurs, and simplifying the entire manufacturing process of the battery unit.

Although a preferred embodiment of the present disclosure has been described for illustrative purposes, those skilled in the art will appreciate that various modifications, additions, and substitutions are possible, without departing from the scope and spirit of the present disclosure as disclosed in the accompanying claims.

What is claimed is:

1. A sensing PCB of a battery unit, the sensing PCB being coupled to the battery unit in which a plurality of cylindrical battery cells, each of which has an upper surface provided with a positive electrode and an negative electrode, are mounted, and being configured to be electrically connected to an electrode network configured to connect the plurality of battery cells in series and parallel and provided in the form of a plurality of separated busbars, and the sensing PCB comprising:
a substrate part provided in a “C” shape and fixedly coupled to the battery unit by a coupling means in a direction of the electrode network of the battery unit;
a plurality of electrode parts provided as a plurality of conductors arranged on a lower surface of the substrate part facing the direction of the electrode network, and configured to make contact with respective ends of the electrode network when the substrate part is fixedly coupled to the battery unit;
a pattern part formed on the substrate part and provided in the form of a printed pattern selectively connected to the plurality of electrode parts; and
an output part located on an upper surface of the substrate part, configured to be electrically connected to the pattern part, having a connection terminal to which an input terminal of a measuring device for measuring an electrical signal is connected, and configured to output an electric signal for each connection section of the electrode network to which the plurality of battery cells are connected through the pattern part.

2. The sensing PCB of claim 1, wherein each of the electrode parts is provided as a conductor having elastic force.

3. The sensing PCB of claim 2, wherein each of the electrode parts is provided in the form of a plate spring convex downward.

4. The sensing PCB of claim 3, wherein each of the electrode parts is brought into close contact with each separation end of the electrode network by the elastic force when the substrate part is fixed to the battery unit in the direction of the electrode network by the coupling means.

5. The sensing PCB of claim 1, wherein the battery unit is provided in a structure in which a first cell group in which a plurality of battery cells form rows and columns, a second cell group in which a plurality of battery cells form rows and columns and spaced apart from the first cell group, and a third cell group in which a plurality of battery cells form rows and columns and disposed between the first and second cell groups are fixedly arranged in a housing so that the positive electrode of each of the battery cells of each of the cell groups faces upward, and the electrode network is disposed on an upper surface of the housing.

6. The sensing PCB of claim 5, wherein the electrode network comprises:
at least one pair of first busbars located on the upper surface of the housing between a row of battery cells and another adjacent row of battery cells that are adjacent in a column direction among the plurality of battery cells of the first and second cell groups, and configured to be connected to the respective positive electrodes of the row of battery cells and the respective negative electrodes of the another adjacent row of battery cells to connect the pluralities of battery cells of the first and second cell groups in parallel in a row direction and in series in the column direction;
a second bus bar configured to connect unconnected electrodes of an outermost row of battery cells in which any one of the positive electrodes and the negative electrodes are connected to the first busbar among the plurality of battery cells of the first and second cell groups, and electrodes of opposite polarities to the unconnected electrodes among the electrodes of a column of battery cells of the third cell group; and
a pair of third busbars configured to be connected to unconnected electrodes of an outermost row of battery cells in which any one of the positive electrodes and the negative electrodes are connected to the first busbar while not being connected to the second busbar among the plurality of battery cells of the first and second cell groups, and each of which has a connection terminal for transmitting power output from the plurality of battery cells connected to the first and second busbars to outside.

7. The sensing PCB of claim 6, wherein the output part outputs an electrical signal for each connection section of the plurality of battery cells through the pattern part, the electrical signal being input from each of the electrode parts electrically connected to the first, second, and third busbars in contact therewith.
